(19) United States
(12) Patent Application Publication
(10) Pub. No.: US 2026/0056245 A1
(43) Pub. Date: Feb. 26, 2026

(54) DETERMINING AN OPERATIONAL LIMIT FOR A TRANSISTOR DEVICE BASED ON GATE OXIDE FAILURE

(71) Applicant: Microchip Technology Inc., Chandler, AZ (US)

(72) Inventors: Mazhar Hoque, Gilbert, AZ (US); Amit Rai, Chandler, AZ (US); Varad Paresh Keni, Tempe, AZ (US); Kashyap Meher, Tempe, AZ (US); Samir Fuke, Tempe, AZ (US); Joseph Rascon, Chandler, AZ (US); Hoi Yun Henry Chan, Lachine (CA)

(73) Assignee: Microchip Technology Inc., Chandler, AZ (US)

(21) Appl. No.: 19/295,189

(22) Filed: Aug. 8, 2025

Related U.S. Application Data
(63) Continuation-in-part of application No. 18/810,767, filed on Aug. 21, 2024.
(63) Continuation-in-part of application No. 19/036,836, filed on Jan. 24, 2025.
(60) Provisional application No. 63/727,456, filed on Dec. 3, 2024.
(60) Provisional application No. 63/811,647, filed on May 24, 2025.

(30) Foreign Application Priority Data
Apr. 30, 2024 (IN) 202411034408

(51) Int. Cl. G01R 31/26

(52) U.S. Cl. CPC G01R 31/2642

(57) ABSTRACT

Systems and methods for determining an operational limit for a transistor are disclosed. The method may include receiving a set of input parameters related to a transistor and performing an analysis of the transistor based on the set of input parameters. The analysis may include performing a simulation of the transistor under time dependent dielectric breakdown conditions by simulating an operation of the transistor and performing a series of lifetime simulations of the transistor. The series of lifetime simulations may include a simulation of an operation of the transistor based on conditions specified by the input parameters and a different value of at least one operational parameter of the transistor. The analysis may further include comparing respective results of the series of lifetime simulations with a target lifetime of the transistor. The method may include determining an operational limit for the transistor based on a result of the analysis.

### PRIORITY

This application is a continuation-in-part of U.S. patent application Ser. No. 18/810,767 filed Aug. 21, 2024, and Ser. No. 19/036,836 filed Jan. 24, 2025, and claims priority to U.S. Provisional Patent Application Nos. 63/811,647 filed May 24, 2025, and 63/727,456 filed Dec. 3, 2024, the contents of which are hereby incorporated in their entirety.

### TECHNICAL FIELD

The present disclosure relates to determining an operational limit for a transistor device.

### BACKGROUND

The performance of electronic circuit components, for example transistors and other semiconductor devices, typically degrades over time due to one or more factors, for example time dependent dielectric breakdown (TDDB). TDDB is a failure mechanism that affects the long-term reliability of insulating materials, particularly the thin dielectric layers used in semiconductor devices like Metal-Oxide-Semiconductor Field-Effect Transistor (MOSFET) gate oxides and inter-layer dielectrics. TDDB is the process by which an insulator, under prolonged electrical stress (i.e., a persistent electric field, often below the intrinsic breakdown strength) and typically at operational or elevated temperatures, gradually degrades and eventually loses its insulating properties. Over time, these defects can form a conductive pathway through the insulator, leading to a sudden and irreversible increase in leakage current or a catastrophic short circuit, ultimately causing the device to fail. TDDB is a concern in modern electronics as device dimensions shrink, leading to higher electric fields across these sensitive layers.

A circuit designer or manufacturer using an Electronic Design Automation (EDA) tool (for example a Cadence, Synopsys, or Ansys EDA platform) to design a circuit, may attempt to determine operational ranges for respective circuit components (e.g., transistors) that allow for long-term operation with acceptable age-related degradation including TDDB. Such operational range is often referred to as a safe operating area (SOA), the extents of which are referred to as SOA limits. Conventional techniques for determining SOA limits include using a spreadsheet (e.g., Excel) or other online calculator. Such techniques are generally primitive, providing a rough estimate of SOA limits, and often inaccurate. Conventional techniques typically involve checking the performance of each circuit component by a largely manual process, performed outside the relevant design environment, e.g., outside the EDA tool used for the relevant circuit design. This largely manual checking of circuit components may be slow and time consuming.

Conventional tools lack the capability to generate a maximum allowable voltage limit for a given application. In addition, for transistor design, conventional tools typically provide a generic maximum operational voltage, without differentiating between drain-source voltage (Vds) and gate-source voltage (Vgs), and typically cannot provide a maximum body-source voltage (Vbs).

Conventional EDA tools typically have some capability to run TDDB simulations, but such simulations can be time-consuming. Still further, EDA tools typically do not have capability to generate maximum allowable voltage limits for a specific application.

### SUMMARY OF THE INVENTION

Aspects provide systems and methods for determining an operational limit for a transistor device.

Alone or in combination with any of the above examples, examples of the present disclosure may include a non-transitory computer-readable medium. The non-transitory computer-readable medium may include instructions executable by a processor. The instructions may cause the processor to receive a set of input parameters related to a transistor device. The instructions may also cause the processor to perform an analysis of the transistor device based on the set of input parameters. The analysis may include performing a simulation of the transistor device under time dependent dielectric breakdown conditions by simulating an operation of the transistor device. The analysis may also include performing a series of lifetime simulations of the transistor device. Each simulation may include a simulation of an operation of the transistor device based on (a) conditions specified by the input parameters and (b) a different value of at least one operational parameter of the transistor device, wherein at least one operational parameter of the transistor device comprises at least one of a gate-source voltage (Vgs), a drain-source voltage (Vds), or a body-source voltage (Vbs). The analysis may further include comparing respective results of the series of lifetime simulations with a target lifetime of the transistor device. The instructions may further cause the processor to determine an operational limit for the transistor device based at least on a result of the analysis of the transistor device, wherein the operational limit comprises a maximum operating value of the gate-source voltage (Vgs), the drain-source voltage (Vds), or the body-source voltage (Vbs).

In combination with any of the above examples, the instructions may be further executable by the processor to apply the operational limit to a circuit design to detect design violations.

In combination with any of the above examples, the operational limit may include a safe operating area (SOA) limit for the transistor device to achieve the target lifetime.

In combination with any of the above examples, the series of lifetime simulations of the transistor device may be performed by a SPICE simulator.

In combination with any of the above examples, the simulation in the series of lifetime simulations of the transistor device may include a simulation of the operation of the transistor device based on (a) the conditions specified by the input parameters and (b) a different parameter value combination for at least two operational parameters of the transistor device.

In combination with any of the above examples, performing the series of lifetime simulations of the transistor device may include performing multiple simulations of the transistor device for each of multiple different values of a first operational parameter of the transistor device. The multiple simulations for a respective value of the first operational parameter may include respective simulations based on (a) the conditions specified by the input parameters, (b) the respective value of the first operational parameter, and (c) multiple different values of a second operational parameter of the transistor device. The analysis may include determining, for each of at least two of the multiple different values of the first operational parameter, a respective limit value derived from results of the multiple simulations performed for the respective value of the first operational parameter. The analysis may also include determining the operational limit for the transistor device based at least on a result of the analysis of the transistor device includes selecting a highest or lowest value of the at least two limit values as the operational limit for the transistor device.

In combination with any of the above examples, the instructions may be further executable by the processor to determine the operational limit for the transistor device based on a duration of an overvoltage stress applied to the transistor device.

In combination with any of the above examples, the simulation of the transistor device may include simulating an effect of the operation of the transistor device on a performance metric specified in the set of input parameters.

In combination with any of the above examples, the performance metric may be a target lifetime or gate leakage current.

Alone or in combination with any of the above examples, examples of the present disclosure may include a non-transitory computer-readable medium. The non-transitory computer-readable medium may include instructions executable by a processor. The instructions may cause the processor to receive a set of input parameters related to a transistor. The instructions may also cause the processor to perform an analysis of the transistor. The analysis may include performing a simulation of the transistor under time dependent dielectric breakdown conditions by simulating an operation of the transistor to determine a value of a performance metric. The analysis may also include performing a series of lifetime simulations of the transistor. Performing a simulation in the series of lifetime simulations may include simulating an operation of the transistor, using (a) conditions specified by the input parameters and (b) a different value of at least one operational parameter of the transistor to determine a respective value of the performance metric corresponding with the respective value of a first operational parameter. The at least one operational parameter of the transistor may be at least one of a gate-source voltage (Vgs), a drain-source voltage (Vds), or a body-source voltage (Vbs). The analysis may further include, for each respective simulation, comparing (a) the respective value of the performance metric corresponding with a target lifetime of the transistor and (b) the value of the performance metric to determine a respective target performance metric corresponding with the respective value of the first operational parameter. The analysis may include determining, based on the respective target performance metric corresponding with the respective values of the first operational parameter, a limit value of the first operational parameter corresponding with a target performance metric. The instructions may further cause the processor to determine an operational limit for the transistor based at least on the determined limit value of the first operational parameter. The operational limit may include a maximum operating value of the gate-source voltage (Vgs), the drain-source voltage (Vds), or the body-source voltage (Vbs).

In combination with any of the above examples, the instructions may be further executable by the processor to apply the operational limit to a circuit design to detect design violations.

In combination with any of the above examples, the operational limit may be a safe operating area (SOA) limit for the transistor to achieve the target lifetime.

In combination with any of the above examples, performing the series of lifetime simulations of the transistor may include performing multiple simulations of the transistor for each of the multiple different values of the first operational parameter of the transistor. The multiple simulations for the respective value of the first operational parameter may include respective simulations based on (a) a condition specified by the input parameters, (b) the respective value of the first operational parameter, and (c) multiple different values of a second operational parameter of the transistor. The analysis may include determining, for each of at least two of the multiple different values of the first operational parameter, a respective limit value derived from results of the multiple simulations performed for the respective value of the first operational parameter. The analysis may also include determining the operational limit for the transistor based at least on a result of the analysis of the transistor includes selecting a highest or lowest value of the at least two limit values as the operational limit for the transistor.

In combination with any of the above examples, the instructions may be further executable by the processor to determine the operational limit for the transistor based on a duration of an overvoltage stress applied to the transistor.

In combination with any of the above examples, the simulation of the transistor may include simulating an effect of the operation of the transistor on the performance metric specified in the set of input parameters.

In combination with any of the above examples, the performance metric may be a target lifetime or gate leakage current.

Alone or in combination with any of the above examples, examples of the present disclosure may include a method. The method may include receiving a set of input parameters related to a transistor device. The method may also include performing an analysis of the transistor device based on the set of input parameters. The analysis may include performing a simulation of the transistor device under time dependent dielectric breakdown conditions by simulating an operation of the transistor device. The analysis may also include performing a series of lifetime simulations of the transistor device. The series of lifetime simulations may include a simulation of an operation of the transistor device based on (a) conditions specified by the input parameters and (b) a different value of at least one operational parameter of the transistor device. The at least one operational parameter of the transistor device may be at least one of a gate-source voltage (Vgs), a drain-source voltage (Vds), or a body-source voltage (Vbs). The analysis may further include comparing respective results of the series of lifetime simulations with a target lifetime of the transistor device. The method may include determining an operational limit for the transistor device based at least on a result of the analysis of the transistor device. The operational limit may be a maximum operating value of the gate-source voltage (Vgs), the drain-source voltage (Vds), or the body-source voltage (Vbs).

In combination with any of the above examples, performing the series of lifetime simulations of the transistor device may include performing multiple simulations of the transistor device for each of multiple different values of a first operational parameter of the transistor device. The multiple simulations for a respective value of the first operational parameter may include respective simulations based on (a) the conditions specified by the input parameters, (b) the respective value of the first operational parameter, and (c) multiple different values of a second operational parameter of the transistor device. The analysis may include determining, for each of at least two of the multiple different values of the first operational parameter, a respective limit value derived from results of the multiple simulations performed for the respective value of the first operational parameter. The analysis may also include determining the operational limit for the transistor device based at least on a result of the analysis of the transistor device includes selecting a highest or lowest value of the at least two limit values as the operational limit for the transistor device.

In combination with any of the above examples, the method may include determining the operational limit for the transistor device based on a duration of an overvoltage stress applied to the transistor device.

Alone or in combination with any of the above examples, examples of the present disclosure may include a system. The system may include an electronic design automation (EDA) tool for development of circuit design including a transistor device. The system may also include an operational limit generation system integrated in the EDA tool. The operational limit generation system may include instructions stored in non-transitory computer-readable medium and executable by a processor. The instructions may cause the processor to receive a set of input parameters related to a transistor device. The instructions may also cause the processor to perform an analysis of the transistor device based on the set of input parameters. The analysis may include performing a simulation of the transistor device under time dependent dielectric breakdown conditions by simulating an operation of the transistor device. The analysis may also include performing a series of lifetime simulations of the transistor device. A simulation of the series of lifetime simulations may include a simulation of an operation of the transistor device based on (a) conditions specified by the input parameters and (b) a different value of at least one operational parameter of the transistor device. The at least one operational parameter of the transistor device may be at least one of a gate-source voltage (Vgs), a drain-source voltage (Vds), or a body-source voltage (Vbs). The analysis may further include comparing respective results of the series of lifetime simulations with a target lifetime of the transistor device. The instructions may further cause the processor to determine an operational limit for the transistor device based at least on a result of the analysis of the transistor device. The operational limit comprises a maximum operating value of the gate-source voltage (Vgs), the drain-source voltage (Vds), or the body-source voltage (Vbs).

### BRIEF DESCRIPTION OF THE DRAWINGS

The figures illustrate examples of systems and methods for determining an operational limit for a transistor device.

FIG. 1 illustrates an example system for generating and analyzing circuit designs using operational limits (e.g., SOA limits) for respective circuit components, according to examples of the present disclosure;

FIG. 2 illustrates an example operational limit generation system for generating operational limit (e.g., an SOA limit) for circuit component (e.g., a transistor), according to examples of the present disclosure;

FIG. 3 illustrates a flowchart of an example method for determining an operational limit (Vmax) for an example circuit component, according to examples of the present disclosure;

FIG. 4 illustrates example graphs illustrating the regression models generated at block 310 described in FIG. 3, according to examples of the present disclosure;

FIG. 5 illustrates example graphs illustrating the safe operating limits as a function of different operating parameters, according to examples of the present disclosure;

FIG. 6 illustrates example graphs illustrating the creation of duration dependent operating limits, according to examples of the present disclosure;

FIG. 7 illustrates a flowchart of an example method 700 for generating an operational limit (e.g., maximum operating voltage) for a transistor device, according to examples of the present disclosure; and

FIG. 8 illustrates a flowchart of another example method 800 for generating an operational limit (e.g., maximum operating voltage) for a transistor device, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, systems and methods for determining an operational limit for a transistor device are provided. The systems and methods may allow for calculation of safe operating area (SOA) limits for time dependent dielectric breakdown (TDDB) failure, without limitation, and account for the effects of TDDB failure. The calculations for determining a safe operational limit for a circuit component, accounting for TDDB failure, may be integrated into an electronic design automation (EDA) tool and used within the design environment. As such, the Vmax limits may be generated and checked for compliance during the design process, potentially reducing the design cycle time because SOA limit checks may be performed at low-level schematic design during the design cycle. The systems and methods may reduce the time and resources used to generate SOA limits and implementing SOA limit checks.

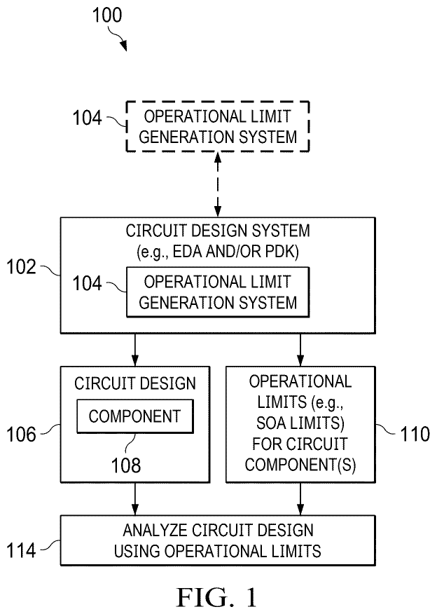

FIG. 1 illustrates an example system for generating and analyzing circuit designs using operational limits (e.g., SOA limits) for respective circuit components, according to examples of the present disclosure. Example system 100 may include circuit design system 102 and operational limit generation system 104. Circuit design system 102 may include any automated or semi-automated system or systems for generating and analyzing a circuit design 106 including various circuit components 108 (e.g., transistors), for example, an electronic design automation (EDA) tool (for example a Cadence, Synopsys, or Ansys EDA platform) to build and analyze circuit designs and/or a physical design kit (PDK) specific to a particular application or technology.

Operational limit generation system 104 may include circuitry to generate operational limits 110 (e.g., SOA limits) for respective circuit components 108 in circuit design 106. Operational limit generation system 104 may generate operational limits 110 for respective circuit components 108 based on respective input parameters (e.g., voltage specifications, operating temperature, minimum lifetime, maximum failure rate). Circuit design system 102 may utilize operational limits 110 generated by operational limit generation system 104 to check circuit design 106 for compliance or design violations (e.g., at various stages during the construction of circuit design 106), as indicated at 114.

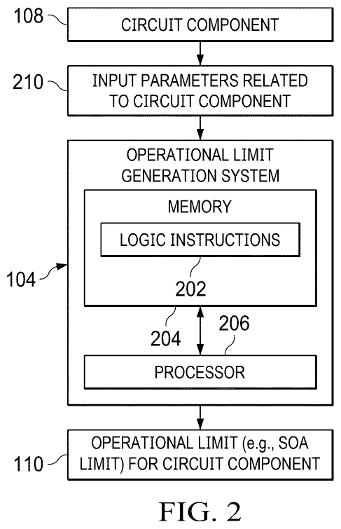

As discussed below with respect to FIG. 2, operational limit generation system 104 may comprise software or other computer-executable instructions stored in non-transitory computer-readable memory and executable by one or more processors. In some examples, operational limit generation system 104 may be integrated in circuit design system 102 (e.g., integrated in an EDA tool). In other examples, operational limit generation system 104 may be separate from circuit design system 102.

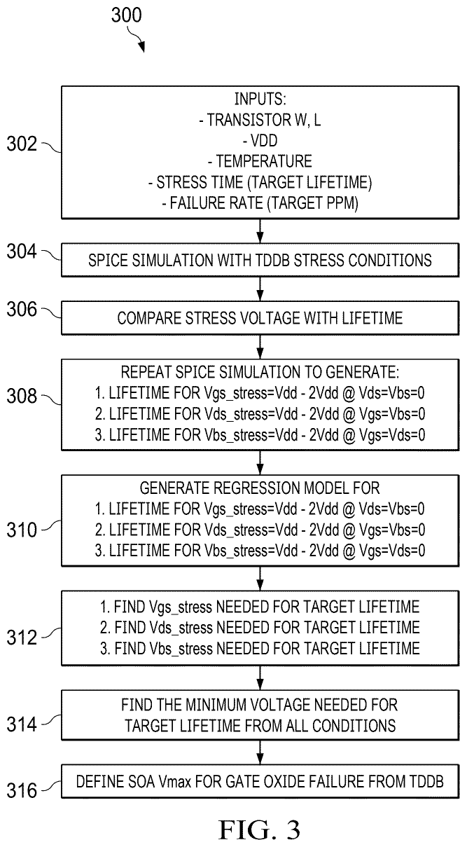

FIG. 2 illustrates an example operational limit generation system for generating operational limit (e.g., an SOA limit) for circuit component (e.g., a transistor), according to examples of the present disclosure. Operational limit 110 may be used by circuit design system 102 to check circuit design 106, as discussed above, according to examples of the present disclosure. As shown, operational limit generation system 104 may include computer-readable logic instructions 202 (e.g., embodied in software and/or firmware) stored in memory 204 and executable by a processor 206 to perform a respective process to generate operational limit 110, for example any of the example processes shown in FIG. 3 and discussed below.

Memory 204 may include one or more type of memory device to store logic instructions 202, for example, read-only memory (ROM), random access memory (RAM, SRAM, DRAM), electrically erasable programmable read-only memory (EEPROM), a PCMCIA card, flash memory, magnetic storage, opto-magnetic storage, hardware registers, and/or any suitable selection or array of volatile or non-volatile memory. Processor 206 may comprise any system, device, or apparatus operable to interpret or execute logic instructions 202, and may include, without limitation a microprocessor, microcontroller, digital signal processor (DSP), application specific integrated circuit (ASIC), or any other digital or analog circuitry to interpret or execute program instructions and/or process data.

As shown in FIG. 2, operational limit generation system 104 may receive input parameters 210 related to circuit component 108 (e.g., a transistor), and generate an operational limit 110 (e.g., a maximum gate voltage) for circuit component 108. FIG. 3 discussed below illustrates example processes implemented by operational limit generation system 104 (e.g., by execution of logic instructions 202 by processor 206) to generate an example operational limit 110 based on example input parameters 210.

FIG. 3 illustrates a flowchart of an example method 300 for determining an operational limit (Vmax) for an example circuit component, according to examples of the present disclosure. Method 300 may be at least partially implemented by operational limit generation system 104 shown in FIG. 2, for example by execution of respective logic instructions 202 (e.g., software) by processor 206, or any other system operable to implement method 300. The discussion of method 300 below is directed to the example transistor simulation; however, the transistor is one example, such that method 300 may be similarly applied to other circuit components. Although examples have been described above, other variations and examples may be made from this disclosure without departing from the spirit and scope of these disclosed examples.

In some examples, method 300 results in a value of Vmax that is adopted as the operational limit (Vmax) for the circuit component. In other examples, method 300 outputs a value of Vmax that is compared with at least one other value of Vmax output by other process(es) to determine the operational limit (Vmax) for the circuit component.

At block 302, the operational limit generation system may receive a set of input parameters related to the example circuit component (e.g., a transistor). For example, the set of input parameters may specify:
(a) dimensions of the circuit component (e.g., width=10 microns, length=100 nm),
(b) maximum operating voltage Vdd (e.g., 0.9V),
(c) maximum operating temperature of the circuit component (e.g., 125° C., maximum junction temperature of transistor),
(d) target lifetime (e.g., 10 years), and
(e) target failure rate (e.g., 1000 ppm).

At block 304, the operational limit generation system may perform aging simulations of the circuit component, for example, based on one or more of the input parameters, for example using a SPICE circuit simulator program. The TDDB simulations may account for TDDB stress conditions. Simulating an operation of the circuit component may include (a) generating a model of the circuit component based on respective input parameters received at block 302 (e.g., dimensions, materials, operating specifications of the circuit component), and (b) operating the model according to respective input parameters received at block 302 (e.g., Vdd, use temperature) to determine a resulting value of a stress voltage specified by the input parameters.

At block 306, the operational limit generation system may compare a stress voltage with the target lifetime of the circuit component. The stress voltage may be a result of the simulations performed at block 304.

At block 308, the operational limit generation system may repeat the process at blocks 304 and 306 to analyze the operational parameters (e.g., Vds, Vgs, Vbs) values using other values above Vdd (e.g., Vgs=Vbs=0 and Vds=Vdd to 2Vdd; Vds=Vbs=0 and Vgs=Vdd to 2Vdd; Vgs=Vds=0 and Vbs=Vdd to 2Vdd, respectively), and the process for analyzing Vds discussed above (i.e., at blocks 304 and 306) may be repeated to analyze Vgs (i.e., by analyzing Vgs through a range of values from Vdd to 2*Vdd), Vds (i.e., by analyzing Vds through a range of values from Vdd to 2*Vdd), and Vbs (i.e., by analyzing Vbs through a range of values from Vdd to 2*Vdd). The operational limit generation system may use selected voltage values (Vds=Vbs=0, Vgs=Vbs=0, Vgs=Vds=0), to generate respective stress voltage results for each combination of parameter values.

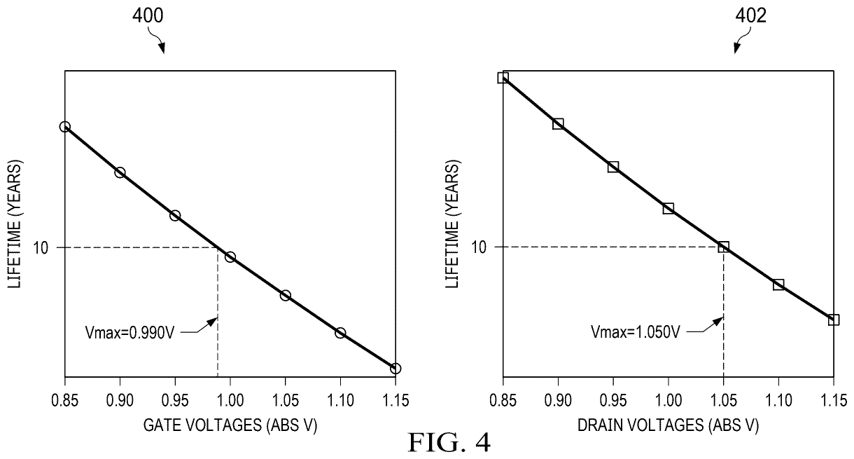

At block 310, the operational limit generation system may generate a regression model for each respective lifetime stress voltage (e.g., Vgs_stress, Vds_stress, Vbs_stress) at the operational parameters (e.g., Vds, Vgs, Vbs). FIG. 4 illustrates example graphs illustrating the regression models generated at block 310 described in FIG. 3, according to examples of the present disclosure.

At block 312, the operational limit generation system may determine a respective limit value (Vmax) for each regression models generated at block 310. For example, as shown in FIG. 4, for graph 400, a respective Vmax limit value for TDDB failure may be determined as the value of Vgs corresponding to the target lifetime (e.g., 10 years) (specified in the input parameters received at block 302). In this example, a limit value of Vmax=0.990V for the gate voltage is determined from graph 400. Similarly, for graph 402, a respective Vmax limit value (1.050V) may be determined as the value of Vds corresponding to the target lifetime (e.g., 10 years). In this example, as shown in FIG. 4, the safe operating area limit may be set to 0.990V.

In some examples, an overall voltage limit value for the circuit component may be selected. In the example in FIG. 4, the overall voltage limit value may be 0.990V, the lowest voltage at which the regression line falls below the target lifetime. In other examples, different voltage limit values may be selected for different terminals of the circuit component. For example, the drain may have a first voltage limit (e.g., 1.050V in FIG. 4), the gate may have a second voltage limit (e.g., 0.990V in FIG. 4), the body may have a third voltage limit, and the source may have a fourth voltage limit.

At block 314, the operational limit generation system may determine a minimum limit value from the various Vmax limit values determined at block 312, in this example Vmax=0.990V shown in graph 400. In this example, this minimum limit value (Vmax=0.990V) may be specified as the operational voltage limit for the transistor with respect to TDDB failure, according to the input parameters received at block 302. The maximum voltage limits may then be used to check a circuit design within a design environment to ensure that the design complies with the maximum allowable voltage limit such that the circuit may perform within the design specifications over the circuits intended lifespan.

Method 300 may be used to generate separate voltage limits for different terminals of the circuit component (e.g., drain, gate, body, source). SOA limits may be generated based on specific use cases of geometry, temperature, lifetime, failure rate, failure criteria, or any combination thereof.

Although FIG. 3 discloses a particular number of operations related to method 300, method 300 may be executed with greater or fewer operations than those depicted in FIG. 3. In addition, although FIG. 3 discloses a certain order of operations to be taken with respect to method 300, the operations comprising method 300 may be completed in any suitable order.

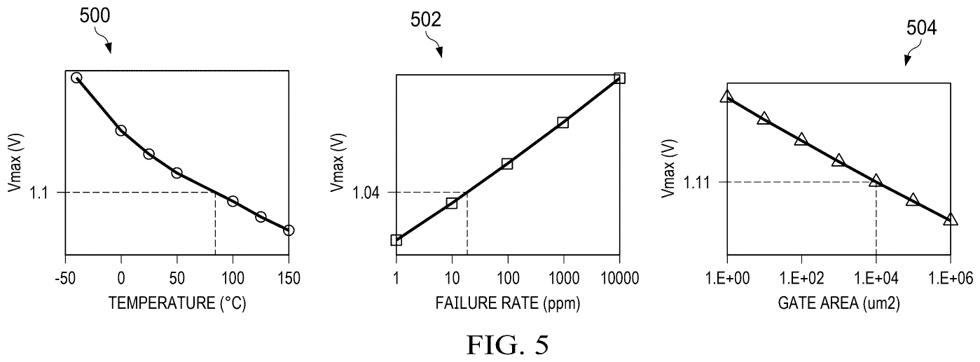

FIG. 5 illustrates example graphs illustrating the safe operating limits as a function of different operating parameters, according to examples of the present disclosure. In the example shown in FIG. 5, rather than basing the voltage limit on the target lifetime of the circuit component (as shown in the example in FIG. 4), the voltage limit may be based on other criteria, including, but not limited to, operating temperature, failure rate, and gate oxide area of the circuit component. In graph 500, the voltage limit is shown as a function of operating temperature. The voltage limit may be determined based on a target operating temperature. For example, at a target operating temperature of approximately 85 degrees Celsius, the voltage limit may be approximately 1.1V.

In graph 502, the voltage limit is shown as a function of failure rate. The voltage limit may be determined based on a target failure rate of the circuit component. For example, at a target failure rate of approximately 20 parts per million, the voltage limit may be approximately 1.04V.

In graph 504, the voltage limit is shown as a function of gate oxide area. The voltage limit may be determined based on a target gate oxide area of the circuit component. For example, at a target gate oxide area of approximately 10,000 micrometers squared (μm²), the voltage limit may be approximately 1.11V.

The overall safe operating limit may be the lowest voltage limit based on the operating parameters for the circuit component. For example, referring to FIGS. 5, the safe operating limit may be 1.04V, the lowest voltage limit for a circuit component having a target operating temperature of 85 degrees, a failure rate of 20 parts per million, and a gate oxide area of 10,000 μm².

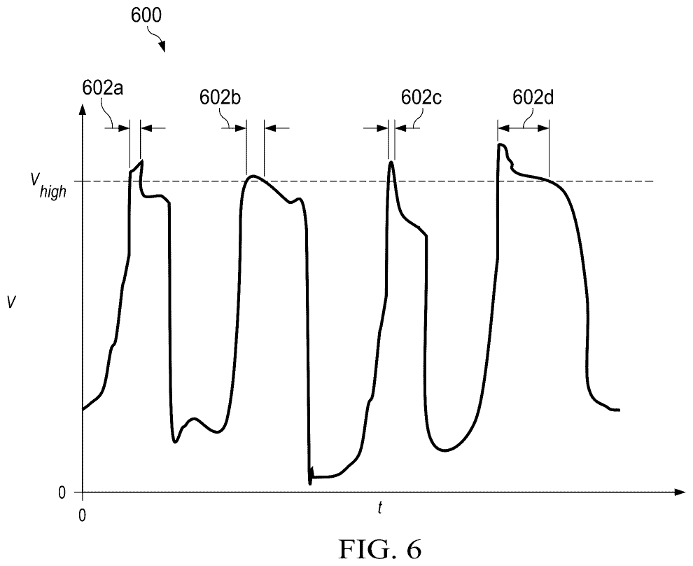

FIG. 6 illustrates example graphs illustrating the creation of duration dependent operating limits, according to examples of the present disclosure. In the example shown in FIG. 6, the circuit component may only experience an over voltage for short, transient time periods 602a, 602b, 602c, and 602d. For the remainder of the operation of the circuit component, the operating voltage may be under the maximum operating voltage (V_{high}). The circuit component may be able to tolerate lower over-voltage stresses for a longer period of time and higher over-voltage stresses for a shorter period of time. Therefore, the voltage limit may be established based on the amount of time that the circuit component may experience over-voltage stresses. For example, as shown in Table 1, based on a target lifetime of 10 years, where the circuit component will experience over-voltage stresses during 100% of its operation, the safe operating voltage limit may be 1.0V. However, as the duration of the over-voltage decreases, the safe operating voltage limit may be increased. Specifically, at a 50% duty cycle, the safe operating voltage limit may be 1.2V and at a 0.10% duty cycle, the safe operating voltage limit may be 1.6V.

TABLE 1
Example Safe Operating Voltage Limit Based On Duty Cycle

| | Duty Cycle for 10 year Lifetime | | | | | |
|---|---|---|---|---|---|---|
| | 100% | 50% | 10% | 1% | 0.50% | 0.10% |
| Lifetime (years) | 10 | 5 | 1 | 0.10 | 0.05 | 0.01 |
| Safe Operating Limit | 1.0 | 1.2 | 1.3 | 1.4 | 1.5 | 1.6 |
| (Vmax) | | | | | | |

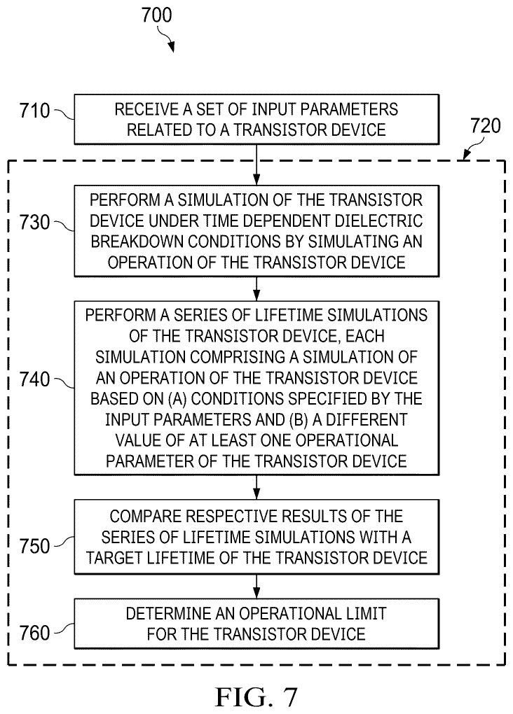

FIG. 7 illustrates a flowchart of an example method 700 for generating an operational limit (e.g., maximum operating voltage) for a transistor device, according to examples of the present disclosure. The example method 700 may be implemented by an operational limit generation system, such as operational limit generation system 104 shown in FIG. 2, for example by execution of respective logic instructions 202 (e.g., software) by processor 206.

At block 710, the operational limit generation system may receive a set of input parameters related to a transistor device, e.g., a transistor device to be included in a circuit design for a particular application. The input parameters may include, for example, characteristics of the transistor device itself (e.g., size, operating specifications), parameters related to an expected operation of the transistor device (e.g., temperature), and/or “TDDB stress conditions” related to the transistor device (e.g., a target lifetime, a failure rate).

At block 720, the operational limit generation system may perform an analysis of the transistor device based on the set of input parameters. The TDDB analysis may include blocks 730-760, which may be performed in any order and may be performed at least partially simultaneously.

At block 730, the operational limit generation system may perform a simulation of the transistor device under time dependent dielectric breakdown conditions by simulating an operation of the transistor device, for example, based on one or more of the input parameters, for example using a SPICE circuit simulator program. Simulating an operation of the transistor device may include (a) generating a model of a of the transistor device based on respective input parameters (e.g., dimensions, materials, operating specifications of the transistor device), and (b) operating the model according to respective input parameters (e.g., Vdd, use temperature) to determine a resulting value of a target performance metric (e.g., a stress voltage over a lifetime of the transistor device) specified by the input parameters.

At block 740, the operational limit generation system may perform a plurality of lifetime simulations of the transistor device. Each lifetime simulation may comprise an extended simulation of an operation of the transistor device based on (a) conditions specified by the input parameters and (b) a different value of at least one operational parameter of the transistor device to determine a respective value of the target performance metric (e.g., a stress voltage over a lifetime of the transistor device) resulting from such simulated operation. In one example, the operational limit generation system may use a SPICE circuit simulator program or other suitable program(s) to generate respective stress voltage results for each combination of parameter values (e.g., Vgs, Vds, and Vbs through a range of values from Vdd to 2*Vdd).

Different operational parameter value(s) (e.g., transistor size, Vdd, temperature, failure rate) may be used for each simulation of the transistor device, to thereby evaluate the effect of varying the operational parameter(s) on the target performance metric. For example, each simulation may use a different combination of Vdd and failure rate values, to evaluate the effect of varying Vdd and/or failure rate on the target performance metric.

At block 750, the operational limit generation system may compare respective results of each simulation from block 740 with a target lifetime of the transistor device.

At block 760, the operational limit generation system may determine an operational limit (e.g., maximum gate, body, or drain voltage) for the transistor device based at least on a result of the analysis of the transistor device. For example, the operational limit generation system may determine from the various comparisons from block 750 a lowest voltage that may violate a performance requirement specified by the input parameters (e.g., target lifetime), and set such lowest voltage as the maximum gate voltage (i.e., operational limit) for the transistor device.

Although FIG. 7 discloses a particular number of operations related to method 700, method 700 may be executed with greater or fewer operations than those depicted in FIG. 7. In addition, although FIG. 7 discloses a certain order of operations to be taken with respect to method 700, the operations comprising method 700 may be completed in any suitable order.

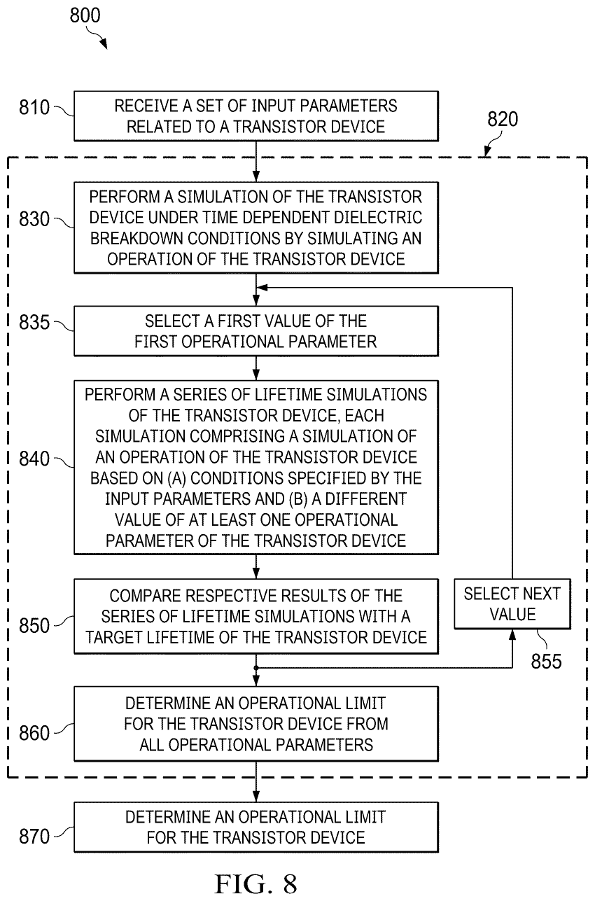

FIG. 8 illustrates a flowchart of another example method 800 for generating an operational limit (e.g., maximum operating voltage) for a transistor device, according to examples of the present disclosure. The example method 800 may be implemented by an operational limit generation system, such as operational limit generation system 104 shown in FIG. 2, for example by execution of respective logic instructions 202 (e.g., software) by processor 206.

At block 810 (similar to block 710 discussed with respect to FIG. 7), the operational limit generation system may receive a set of input parameters related to a transistor device, e.g., a transistor device to be included in a circuit design for a particular application.

At block 820, the operational limit generation system may perform an analysis of the transistor device based on the set of input parameters. The analysis may include blocks 830-860, which may be performed in any order and may be performed at least partially simultaneously.

At block 830, the operational limit generation system may perform a simulation of the transistor device by simulating an operation of the transistor device, for example, based on one or more of the input parameters, for example using a SPICE circuit simulator program. As discussed above, simulating an operation of the transistor device may include (a) generating a model of the transistor device based on respective input parameters (e.g., dimensions, materials, operating specifications, of the transistor device), and (b) operating the model according to respective input parameters (e.g., Vdd, use temperature) to determine a resulting value of a target performance metric (e.g., a stress voltage over a lifetime of the transistor device) specified by the input parameters.

At blocks 835-850, the operational limit generation system may analyze a first operational parameter of the transistor device (e.g., Vds) to generate data for determining a limit value of the first operational parameter at block 860.

At block 835, the operational limit generation system may select a first value of the first operational parameter (e.g., Vds=Vdd, wherein Vdd is specified by the input parameters).

At block 840, the operational limit generation system may perform one or more lifetime simulations of the transistor device using the first value of the first operational parameter (e.g., Vds=Vdd). Each simulation may comprise an extended simulation of an operation of the transistor device based on (a) conditions specified by the input parameters and (b) the first value of the first operational parameter (e.g., Vds=Vdd) to determine a value of the target performance metric (e.g., a stress voltage over a lifetime of the transistor device) resulting from such simulated operation.

In some examples, multiple simulations are performed using the first value of the first operational parameter (e.g., Vds=Vdd), for example using a different value of a second operational parameter (e.g., Vgs) for each respective simulation. Thus, each simulation from block 840 may use (a) conditions specified by the input parameters, (b) the first value of the first operational parameter (e.g., Vds=Vdd), and (c) a different value of the second operational parameter (e.g., Vgs=0, Vgs=Vdd/2, and Vgs=Vdd for three distinct simulations), to determine respective value of the target performance metric (e.g., lifetime of the transistor device) resulting from such simulated operation. Vds and Vgs values applied during a simulation may be referred to herein as Vds_stress and Vgs_stress, respectively.

In some examples, the operational limit generation system may use a SPICE circuit simulator program or other suitable program(s) for each simulation, wherein the first value of the first operational parameter (e.g., Vds=Vdd) and the respective value of the second operational parameter (e.g., Vgs=0, Vdd/2, or Vdd) for the target lifetime specified by the input parameters, which may alter certain characteristics of the transistor device (e.g., gate oxide charge, electron/hole mobility). The simulator program (e.g., a SPICE simulator) may then generate a model of the transistor device based on the altered characteristics of the transistor device, and operate the model to determine a respective value of the target performance metric (e.g., a stress voltage over a lifetime of the transistor device).

At block 850, the operational limit generation system may compare respective results of each TDDB simulation from block 840 with the results a target lifetime of the transistor device.

At block 855, the operational limit generation system may then select a next value (e.g., a second value) for the first operational parameter (e.g., Vds=1.2*Vdd) and repeat the process of blocks 840 and 850. The operational limit generation system may continue this process for all values of the first operational parameter to be tested, for example for a range of values of Vds from Vdd to 2*Vdd.

At block 860, the operational limit generation system may determine a limit value for the first operational parameter based on the results of the analysis at blocks 835-850, for example based on the respective change in the performance metric (e.g., lifetime) resulting from each iteration, i.e., the lifetime resulting from each selected combination of Vds and Vgs values.

At block 870, the operational limit generation system may determine an operational limit of the transistor device (e.g., maximum gate voltage of a transistor) based at least on the limit value determined at block 860. For example, as discussed with reference to FIG. 3, the operational limit generation system may repeat the analysis at block 820 for additional operational parameter(s) (e.g., the second operational parameter (Vgs)) and determine respective limit value(s) for such operational parameter(s), which may be compared with the limit value for the first operational parameter (Vds) to determine the operational limit of the transistor device, e.g., by selecting the lowest determined limit value.

Although FIG. 8 discloses a particular number of operations related to method 800, method 800 may be executed with greater or fewer operations than those depicted in FIG. 8. In addition, although FIG. 8 discloses a certain order of operations to be taken with respect to method 800, the operations comprising method 800 may be completed in any suitable order.

Although examples have been described above, other variations and examples may be made from this disclosure without departing from the spirit and scope of these disclosed examples.

1. A non-transitory computer-readable medium comprising instructions executable by a processor to:
receive a set of input parameters related to a transistor device;
perform an analysis of the transistor device based on the set of input parameters, including:
performing a simulation of the transistor device under time dependent dielectric breakdown conditions by simulating an operation of the transistor device;
performing a series of lifetime simulations of the transistor device, each simulation comprising a simulation of an operation of the transistor device based on (a) conditions specified by the input parameters and (b) a different value of at least one operational parameter of the transistor device, wherein at least one operational parameter of the transistor device comprises at least one of a gate-source voltage (Vgs), a drain-source voltage (Vds), or a body-source voltage (Vbs);
comparing respective results of the series of lifetime simulations with a target lifetime of the transistor device; and
determine an operational limit for the transistor device based at least on a result of the analysis of the transistor device, wherein the operational limit comprises a maximum operating value of the gate-source voltage (Vgs), the drain-source voltage (Vds), or the body-source voltage (Vbs).

2. The non-transitory computer-readable medium of claim 1, wherein the instructions are further executable by the processor to apply the operational limit to a circuit design to detect design violations.

3. The non-transitory computer-readable medium of claim 1, wherein the operational limit includes a safe operating area (SOA) limit for the transistor device to achieve the target lifetime.

4. The non-transitory computer-readable medium of claim 1, wherein the series of lifetime simulations of the transistor device are performed by a SPICE simulator.

5. The non-transitory computer-readable medium of claim 1, wherein the simulation in the series of lifetime simulations of the transistor device includes a simulation of the operation of the transistor device based on (a) the conditions specified by the input parameters and (b) a different parameter value combination for at least two operational parameters of the transistor device.

6. The non-transitory computer-readable medium of claim 1, wherein:
performing the series of lifetime simulations of the transistor device includes performing multiple simulations of the transistor device for each of multiple different values of a first operational parameter of the transistor device, wherein the multiple simulations for a respective value of the first operational parameter include respective simulations based on (a) the conditions specified by the input parameters, (b) the respective value of the first operational parameter, and (c) multiple different values of a second operational parameter of the transistor device;
the analysis includes:
determining, for each of at least two of the multiple different values of the first operational parameter, a respective limit value derived from results of the multiple simulations performed for the respective value of the first operational parameter; and
determining the operational limit for the transistor device based at least on a result of the analysis of the transistor device includes selecting a highest or lowest value of the at least two limit values as the operational limit for the transistor device.

7. The non-transitory computer-readable medium of claim 1, wherein the instructions are further executable by the processor to determine the operational limit for the transistor device based on a duration of an overvoltage stress applied to the transistor device.

8. The non-transitory computer-readable medium of claim 1, wherein the simulation of the transistor device includes simulating an effect of the operation of the transistor device on a performance metric specified in the set of input parameters.

9. The non-transitory computer-readable medium of claim 8, wherein the performance metric is a target lifetime or gate leakage current.

10. A non-transitory computer-readable medium comprising instructions executable by a processor to:
receive a set of input parameters related to a transistor;
perform an analysis of the transistor, including:
performing a simulation of the transistor under time dependent dielectric breakdown conditions by simulating an operation of the transistor to determine a value of a performance metric;
performing a series of lifetime simulations of the transistor, wherein performing a simulation in the series of lifetime simulations includes simulating an operation of the transistor, using (a) conditions specified by the input parameters and (b) a different value of at least one operational parameter of the transistor, wherein the at least one operational parameter of the transistor comprises at least one of a gate-source voltage (Vgs), a drain-source voltage (Vds), or a body-source voltage (Vbs), to determine a respective value of the performance metric corresponding with the respective value of a first operational parameter;
for each respective simulation, comparing (a) the respective value of the performance metric corresponding with a target lifetime of the transistor and (b) the value of the performance metric to determine a respective target performance metric corresponding with the respective value of the first operational parameter;
determining, based on the respective target performance metric corresponding with the respective values of the first operational parameter, a limit value of the first operational parameter corresponding with a target performance metric; and
determine an operational limit for the transistor based at least on the determined limit value of the first operational parameter, wherein the operational limit comprises a maximum operating value of the gate-source voltage (Vgs), the drain-source voltage (Vds), or the body-source voltage (Vbs).

11. The non-transitory computer-readable medium of claim 10, wherein the instructions are further executable by the processor to apply the operational limit to a circuit design to detect design violations.

12. The non-transitory computer-readable medium of claim 10, wherein the operational limit is a safe operating area (SOA) limit for the transistor to achieve the target lifetime.

13. The non-transitory computer-readable medium of claim 10, wherein:
performing the series of lifetime simulations of the transistor includes performing multiple simulations of the transistor for each of the multiple different values of the first operational parameter of the transistor, wherein the multiple simulations for the respective value of the first operational parameter include respective simulations based on (a) a condition specified by the input parameters, (b) the respective value of the first operational parameter, and (c) multiple different values of a second operational parameter of the transistor;
the analysis includes:
determining, for each of at least two of the multiple different values of the first operational parameter, a respective limit value derived from results of the multiple simulations performed for the respective value of the first operational parameter; and
determining the operational limit for the transistor based at least on a result of the analysis of the transistor includes selecting a highest or lowest value of the at least two limit values as the operational limit for the transistor.

14. The non-transitory computer-readable medium of claim 10, wherein the instructions are further executable by the processor to determine the operational limit for the transistor based on a duration of an overvoltage stress applied to the transistor.

15. The non-transitory computer-readable medium of claim 10, wherein the simulation of the transistor includes simulating an effect of the operation of the transistor on the performance metric specified in the set of input parameters.

16. The non-transitory computer-readable medium of claim 15, wherein the performance metric is a target lifetime or gate leakage current.

17. A method, comprising:
receiving a set of input parameters related to a transistor device;
performing an analysis of the transistor device based on the set of input parameters, including:
performing a simulation of the transistor device under time dependent dielectric breakdown conditions by simulating an operation of the transistor device;
performing a series of lifetime simulations of the transistor device, wherein the series of lifetime simulations including a simulation of an operation of the transistor device based on (a) conditions specified by the input parameters and (b) a different value of at least one operational parameter of the transistor device, wherein the at least one operational parameter of the transistor device comprises at least one of a gate-source voltage (Vgs), a drain-source voltage (Vds), or a body-source voltage (Vbs);
comparing respective results of the series of lifetime simulations with a target lifetime of the transistor device; and
determining an operational limit for the transistor device based at least on a result of the analysis of the transistor device, wherein the operational limit comprises a maximum operating value of the gate-source voltage (Vgs), the drain-source voltage (Vds), or the body-source voltage (Vbs).

18. The method of claim 17, wherein:
performing the series of lifetime simulations of the transistor device includes performing multiple simulations of the transistor device for each of multiple different values of a first operational parameter of the transistor device, wherein the multiple simulations for a respective value of the first operational parameter includes respective simulations based on (a) the conditions specified by the input parameters, (b) the respective value of the first operational parameter, and (c) multiple different values of a second operational parameter of the transistor device;
the analysis includes:
determining, for each of at least two of the multiple different values of the first operational parameter, a respective limit value derived from results of the multiple simulations performed for the respective value of the first operational parameter; and
determining the operational limit for the transistor device based at least on a result of the analysis of the transistor device includes selecting a highest or lowest value of the at least two limit values as the operational limit for the transistor device.

19. The method of claim 17, comprising determining the operational limit for the transistor device based on a duration of an overvoltage stress applied to the transistor device.

20. A system, comprising:
an electronic design automation (EDA) tool for development of circuit design including a transistor device;
an operational limit generation system integrated in the EDA tool, the operational limit generation system including instructions stored in non-transitory computer-readable medium and executable by a processor to:
receive a set of input parameters related to a transistor device;
perform an analysis of the transistor device based on the set of input parameters, including:
performing a simulation of the transistor device under time dependent dielectric breakdown conditions by simulating an operation of the transistor device;
performing a series of lifetime simulations of the transistor device, a simulation of the series of lifetime simulations including a simulation of an operation of the transistor device based on (a) conditions specified by the input parameters and (b) a different value of at least one operational parameter of the transistor device, wherein the at least one operational parameter of the transistor device comprises at least one of a gate-source voltage (Vgs), a drain-source voltage (Vds), or a body-source voltage (Vbs);
comparing respective results of the series of lifetime simulations with a target lifetime of the transistor device; and
determine an operational limit for the transistor device based at least on a result of the analysis of the transistor device, wherein the operational limit comprises a maximum operating value of the gate-source voltage (Vgs), the drain-source voltage (Vds), or the body-source voltage (Vbs).
